(19) United States
(12) Patent Application Publication
(10) Pub. No.: US 2025/0334652 A1
(43) Pub. Date: Oct. 30, 2025

(54) CYCLIC CHANNEL SELF EVALUATION

(71) Applicant: Allegro MicroSystems, LLC, Manchester, NH (US)

(72) Inventors: Juan Manuel Cesaretti, Buenos Aires (AR); Franco Noel Martin Pirchio, Buenos Aires (AR); Dominic Palermo, Haverhill, MA (US)

(73) Assignee: Allegro MicroSystems, LLC, Manchester, NH (US)

(21) Appl. No.: 18/647,130

(22) Filed: Apr. 26, 2024

(51) Int. Cl. G01R 33/00; G01R 33/07

(52) U.S. Cl. CPC G01R 33/0023; G01R 33/07

(57) ABSTRACT

A system and method are disclosed to test signal paths within sensor signal channels by providing an additional signal channel having testing means. The additional signal channel has a test signal generator, a test signal evaluator, and a signal path that is provided in parallel to existing signal paths within the sensor. Signal paths between each sensing element and each output are manipulated by input and output path couplers so that sense signals always reach the correct outputs but the intermediary signal path(s) may be changed according to a self-test protocol. In particular, the signal path(s) may be selected for cyclical testing. The signal path under test is subjected to test signals from the test signal generator which are then evaluated by the test signal evaluator for correctness, and faults signaled. The test signals may be selected to test each signal processing function in the signal path.

### FIELD

The disclosure pertains generally to measuring magnetic variables, and more particularly to self-testing of signal channels within magnetic field sensors.

### BACKGROUND

Many automobile manufacturers and parts suppliers follow the ISO 26262 safety standard promulgated by the International Organization for Standardization (ISO). This standard provides a common vocabulary for discussing vehicle safety issues, and discusses safety management, the safety life cycle, supporting processes, and the Automotive Safety Integrity Level (ASIL).

FIG. 1 shows timing diagrams for three vehicle-level systems covered by ISO 26262 (also called “items” therein) according to whether they include a safety mechanism, and whether the safety mechanism is implemented with an emergency operation. Vehicle-level systems perform a function that is observable by the customer (such as automatic cruise control or collision avoidance) using sensors, electronic control units (ECUs), and actuators. The top panel of FIG. 1 represents a system without a safety mechanism, indicating a time between a fault causing malfunctioning behavior of the item and that behavior resulting in a hazardous event. The middle panel represents a system with a failsafe mechanism implemented, indicating diagnostic tests being performed and a transition to a safe state before a hazardous event occurs. The bottom panel represents a system with an emergency operation (e.g., a corrective steering action) followed by a failsafe.

Sensors have several elements that communicate using internal signal channels. Thus, for example, a magnetic field sensor has one or more magnetic field sensing elements connected to one or more outputs using interposed signal channels. These signal channels may include various functional blocks such as signal amplifiers, signal filters, and so on, in a series circuit. Single point failures in such functional blocks are difficult to detect from the outputs, due to the signal paths being combined. Providing full redundancy is expensive because it doubles the size of the sensor, while monitoring direct current conditions inside each signal processing block itself in a constant self-test is nearly as expensive. Therefore, another solution is needed for products requiring high ASIL ratings.

### SUMMARY OF DISCLOSED EMBODIMENTS

Disclosed embodiments supplement the signal channel(s) in an existing sensor by adding an additional signal channel having testing means. The additional channel includes a test signal generator, a test signal evaluator, and a signal path in parallel with the signal paths between the sensing elements and the sensor outputs. The combined set of signal paths is multiplexed, so that the signal path carrying sense data from each sensing element can be selectively carried to any output path, thereby maintaining constant sensor output. The addition of the parallel signal path allows any other desired signal path to be temporarily taken offline, being instead connected to the test signal generator and test signal evaluator for testing. Isolating each signal path in this manner allows for its main signal processing functions to be thoroughly assessed before being placed back into service. This type of self-evaluation of signal paths may advantageously be done cyclically, so that one may guarantee that each signal path has been tested within a fixed prior duration, e.g. a fault detection time interval.

Thus, a first embodiment is a sensor comprising a housing that includes a first path coupler and a second path coupler, wherein outputs of the first path coupler are coupled to respective inputs of the second path coupler via a plurality of signal paths. The sensor includes a sensing element and a test signal generator, each coupled to a different input of the first path coupler. The sensor includes a sensor output and a test signal evaluator, each coupled to a different output of the second path coupler. And the sensor includes a control circuit coupled to and configuring the first and second path couplers to connect test signals, produced by the test signal generator, to the test signal evaluator through a selected signal path in the plurality of signal paths, while maintaining a data connection between the sensing element and the sensor output using a non-selected signal path in the plurality of signal paths. In embodiments, the control circuit is configured to change the selected signal path over time according to a self-test protocol.

In some embodiments, the sensor comprises a magnetic field sensor and the sensing element comprises one or more magnetic field sensing elements.

In some embodiments, the test signal generator comprises a circuit configured to generate signals to test different signal processes performed within a signal path in the plurality of signal paths.

In some embodiments, the test signal generator comprises a circuit configured to generate an amplifier gain test signal, or a notch filter offset test signal, or both.

In some embodiments, each signal path in the plurality of signal paths comprises an amplifier, or a notch filter, or both.

In some embodiments, the control circuit is configured to select signal paths cyclically for testing.

In some embodiments, the self-test protocol includes a plurality of phases, each phase consisting of: (a) disconnecting the selected signal path from the sensing element and the sensor output, and connecting the selected signal path to the test signal generator and the test signal evaluator; or (b) evaluating, by the test signal evaluator, a test signal generated by the test signal generator and processed by the selected signal path; or (c) disconnecting the selected signal path from the test signal generator and the test signal evaluator, and connecting the selected signal path to the sensing element and the sensor output.

In some embodiments, the self-test protocol includes identifying two signal paths that each maintain a data connection between the sensing element and the sensor output; and selecting one of the two identified signal paths for testing.

In some embodiments, the sensing element comprises a plurality of sensing elements, each coupled to a different input of the first path coupler, and maintaining the data connection comprises maintaining a data connection between the plurality of sensing elements and the sensor output.

In some embodiments, the sensor output comprises a plurality of sensor outputs, each coupled to a different output of the second path coupler, and maintaining the data connection comprises maintaining a data connection between the sensing element and the plurality of sensor outputs.

Another embodiment is a method of testing a sensor within a housing, the sensor comprising a first path coupler and a second path coupler wherein outputs of the first path coupler are coupled to respective inputs of the second path coupler via a plurality of signal paths. The method includes selecting a signal path in the plurality of signal paths for testing. And the method includes, responsive to the selecting, configuring the first and second path couplers to connect test signals, produced by a test signal generator connected to a first input of the first path coupler, through the selected signal path to a test signal evaluator connected to a first output of the second path coupler, while maintaining a data connection between a sensing element connected to a second input of the first path coupler and a sensor output connected to a second output of the second path coupler. Selecting the signal path comprises changing the selected signal path over time according to a self-test protocol.

In some embodiments, the sensor comprises a magnetic field sensor and the sensing element comprises one or more magnetic field sensing elements.

Some embodiments further include the test signal generator generating test signals to test different signal processes performed within a signal path in the plurality of signal paths.

In some embodiments, the test signals comprise an amplifier gain test signal, or a notch filter offset test signal, or both.

In some embodiments, each signal path in the plurality of signal paths comprises an amplifier, or a notch filter, or both.

In some embodiments, selecting the signal path comprises selecting signal paths cyclically for testing.

In some embodiments, the self-test protocol includes a plurality of phases, each phase consisting of: (a) disconnecting the selected signal path from the sensing element and the sensor output, and connecting the selected signal path to the test signal generator and the test signal evaluator; or (b) evaluating, by the test signal evaluator, a test signal generated by the test signal generator and processed by the selected signal path; or (c) disconnecting the selected signal path from the test signal generator and the test signal evaluator, and connecting the selected signal path to the sensing element and the sensor output.

In some embodiments, the self-test protocol includes identifying two signal paths that each maintain a data connection between the sensing element and the sensor output; and selecting one of the two identified signal paths for testing.

In some embodiments, the sensing element comprises a plurality of sensing elements, each coupled to a different input of the first path coupler, and maintaining the data connection comprises maintaining a data connection between the plurality of sensing elements and the sensor output.

In some embodiments, the sensor output comprises a plurality of sensor outputs, each coupled to a different output of the second path coupler, and maintaining the data connection comprises maintaining a data connection between the sensing element and the plurality of sensor outputs.

It is appreciated that the concepts, techniques, and structures disclosed herein may be embodied in other ways, and that the above summary of disclosed embodiments is thus meant to be illustrative rather than comprehensive or limiting. In particular, individual elements of different embodiments described herein may be combined to form other embodiments not specifically set forth above. Various elements, which are described in the context of a single embodiment, also may be provided in other embodiments separately, or in any suitable sub-combination. Moreover, other embodiments not specifically described herein also may be within the scope of the claims set forth below.

### DESCRIPTION OF THE SEVERAL VIEWS OF THE DRAWINGS

The manner and process of making and using the disclosed embodiments may be appreciated by reference to the drawings, in which:

FIG. 1 shows timing diagrams known in the art for three vehicle-level systems according to whether they include a safety mechanism, and whether the safety mechanism is implemented with an emergency operation;

FIG. 2 schematically shows relevant components of a sensor having a sensing element and a test generator according to an embodiment of the concepts, techniques, and structures disclosed herein;

FIG. 3 shows a timing diagram for a self-test protocol according to an embodiment that may be performed by the sensor of FIG. 2;

FIGS. 3A-3F schematically show the operation of the system of FIG. 2 at respective phases of the timing diagram shown in FIG. 3;

FIG. 4 schematically shows relevant components of a system having three magnetic field sensing elements and a test generator according to another embodiment;

FIG. 5 shows a timing diagram for a method according to an embodiment that may be performed by the system of FIG. 4; and

FIG. 6 is a flow diagram for a method according to various embodiments.

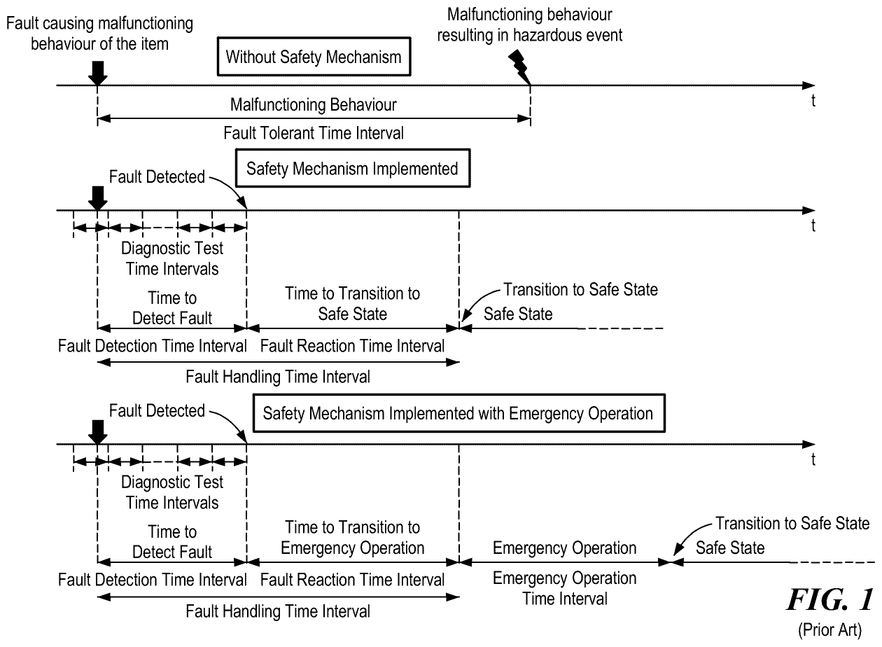

### DETAILED DESCRIPTION OF EMBODIMENTS

In this specification, including the appended claims, the following quoted terms shall have the indicated meanings that are not limited to specific embodiments, except where expressly indicated otherwise:

As used herein, the term “fault tolerant time interval” (or “FTTI”) has the meaning given by ISO 26262, namely the minimum time span from occurrence of a fault in an item to occurrence of a hazardous event, if a safety mechanism is not activated.

As used herein, the term “fault handling time interval” (or “FHTI”) has the meaning given by ISO 26262, namely the sum of the fault detection time interval and the fault reaction time interval.

As used herein, the term “fault detection time interval” has the meaning given by ISO 26262, namely the time-span from the occurrence of a fault to the detection of a fault.

As used herein, the term “fault reaction time interval” has the meaning given by ISO 26262, namely the time-span from the detection of a fault to reaching the safe state or to reaching emergency operation.

As used herein, the term “sensing element” is used to describe a variety of electronic elements that can sense (i.e., measure) properties of an ambient environment.

As used herein, the term “magnetic field sensing element” is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate or in the plane of the substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

As used herein, the term “magnetic field signal” is used to describe any signal that results from a magnetic field experienced by a magnetic field sensing element.

As used herein, the term “sensor” is used to describe a circuit that uses one or more sensing elements, generally in combination with other circuits. A sensor can be, for example, a rotation detector, a movement detector, a current sensor, or a proximity detector.

As used herein, the term “magnetic field sensor” is used to describe a sensor that uses one or more magnetic field sensing elements. A rotation detector can sense rotation of a magnetic object, for example, advance and retreat of magnetic domains of a ring magnet or advance and retreat of gear teeth of a ferromagnetic gear. The term “movement detector” can be used to describe either a rotation detector or a magnetic field sensor that can sense different movement, e.g., linear movement, of a ferromagnetic object, for example, linear movement of magnetic domains of a ring magnet or linear movement of gear teeth of a ferromagnetic gear.

Magnetic field sensors are used in a variety of applications, including, but not limited to an angle sensor that senses an angle of a direction of a magnetic field, a current sensor that senses a magnetic field generated by a current carried by a current-carrying conductor, a magnetic switch that senses the proximity of a ferromagnetic object, a rotation detector (or movement detector) that senses passing ferromagnetic articles, for example, magnetic domains of a ring magnet or a ferromagnetic target (e.g., gear teeth) where the magnetic field sensor is used in combination with a back-bias or other magnet, and a magnetic field sensor that senses a magnetic field density of a magnetic field. The circuits and techniques described herein apply to any magnetic field sensor capable of detecting a magnetic field.

As used herein, the terms “processor” and “controller” are used to describe elements that perform a function, an operation, or a sequence of operations. The function, operation, or sequence of operations can be hard coded into an electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a discrete electronic circuit which can be analog or digital, and/or in special purpose logic circuitry (e.g., a field programmable gate array (FPGA)). Processing can be implemented in hardware, software, or a combination of the two. Processing can be implemented using computer programs executed on programmable computers/machines that include one or more processors, a storage medium or other article of manufacture that is readable by the processor (including volatile and non-volatile memory and/or storage elements), at least one input device and one or more output devices. Program code can be applied to data entered using an input device to perform processing and to generate output information. A processor or controller can contain internal processors or modules that perform portions of the function, operation, or sequence of operations. Similarly, a module can contain internal processors or internal modules that perform portions of the function, operation, or sequence of operations of the module.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

It should be understood that a so-called “comparator” can be comprised of an analog comparator having a two-state output signal indicative of an input signal being above or below a threshold level (or indicative of one input signal being above or below another input signal). However, the comparator can also be comprised of a digital circuit having an output signal with at least two states indicative of an input signal being above or below a threshold level (or indicative of one input signal being above or below another input signal), respectively, or a digital value above or below a digital threshold value (or another digital value), respectively.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

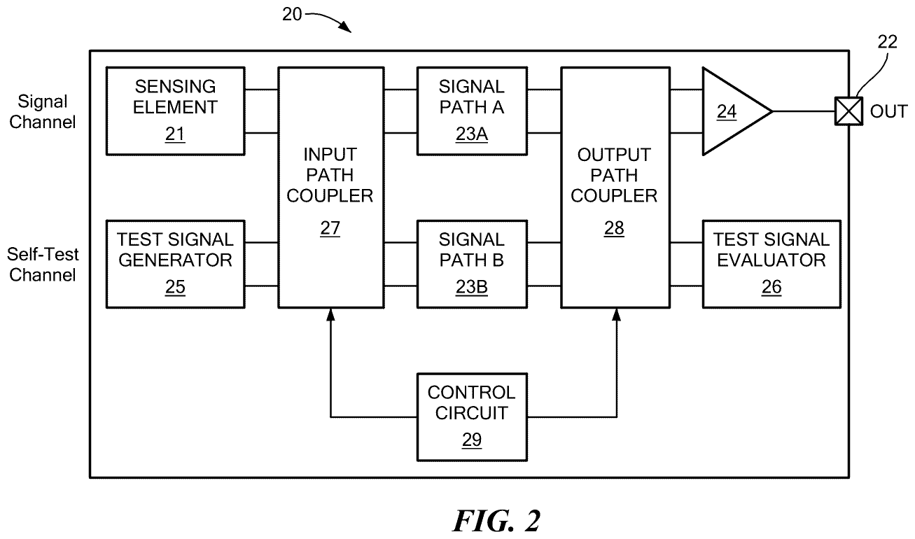

FIG. 2 schematically shows relevant components of a sensor 20 according to an embodiment of the concepts, techniques, and structures disclosed herein. The sensor 20 may be presented in a number of different ways known in the art including as a “chip”, i.e., an integrated circuit (“IC”) within a semiconductor package (“housing”). It is appreciated that a person having ordinary skill in the art would know of other presentations and other housings that may be used without deviating from the teachings herein.

It is known in the art to have a signal channel comprising a sensing element 21 connected to a sensor output 22 via a first signal path 23A within a housing. In what follows, the sensor 20 is described as being a magnetic field sensor for purposes of illustration, not to limit the scope of embodiments, and it is appreciated that other sensors may be embodied in accordance with the concepts, techniques, and structures disclosed herein. Thus, for example, the sensing element 21 may include one or more Hall elements for producing an output voltage that is proportional to a sensed magnetic field. The signal path 23A may include electronic signal processing blocks (e.g., amplifiers, notch filters, and so on) to produce an output signal that represents a desired computation (e.g., a sine or cosine of a direction of the magnetic field relative to an axis of the sensor). It is also known to boost the output signal using an output amplifier 24 to achieve a calibrated output level according to a published sensor specification.

However, in accordance with the concepts, techniques, and structures of embodiments disclosed herein, the housing of the sensor 20 also includes a test signal generator 25, a second signal path 23B, and a test signal evaluator 26. The second signal path 23B is electrically parallel to the first signal path 23A, and is comprised of identical or similar signal processing blocks as the first signal path 23A.

In accordance with embodiments, the test signal generator 25 comprises a circuit configured to generate signals to test different signal processes performed within a signal path, and the test signal evaluator 26 determines whether a signal path operates on given input signals appropriately. These processes may be any analog or digital signal processes known in the art. For example, if the signal path contains an amplifier, then the test signal generator 25 can generate a signal to be amplified and the test signal evaluator 26 should be able to detect the gain on the test signal. Likewise, if the signal path contains a notch filter (i.e., a filter that blocks only those signals within a specified frequency range) then the test signal generator 25 generates a signal that will have a known frequency (or a sequence of signals with varying frequencies) and the test signal evaluator 26 determines which signal(s) passed through the notch filter. The test signal generator 25 and evaluator 26 may be implemented using known techniques for circuitry design.

The parallel signal paths 23A, 23B are surrounded by an input path coupler 27 and an output path coupler 28. The path couplers 27, 28 are controlled by a control circuit 29 so that each input signal to the input coupler 27 is routed to its corresponding output of the output coupler 28 along a selected signal path. That is, in the example of FIG. 2, signals from the sensing element 21 are connected to the sensor output 22 as they would be without presence of the elements described herein, but the control circuit 29 determines whether those signals are routed through the first signal path 23A or the second signal path 23B. Similarly, signals from the test signal generator 25 are routed to the test signal evaluator 26, and the control circuit 29 determines whether they are routed through the first signal path 23A or the second signal path 23B without interfering with the signals from the sensing element 21.

The input path coupler 27 and output path coupler 28 may be implemented using standard circuitry including switches, multiplexers, demultiplexers, and other circuits known in the art. The control circuit 29 also may be implemented using known circuitry, and may include a counter to provide cyclical selection of signal paths as described below. It is appreciated that these electronic components also may be implemented in other ways.

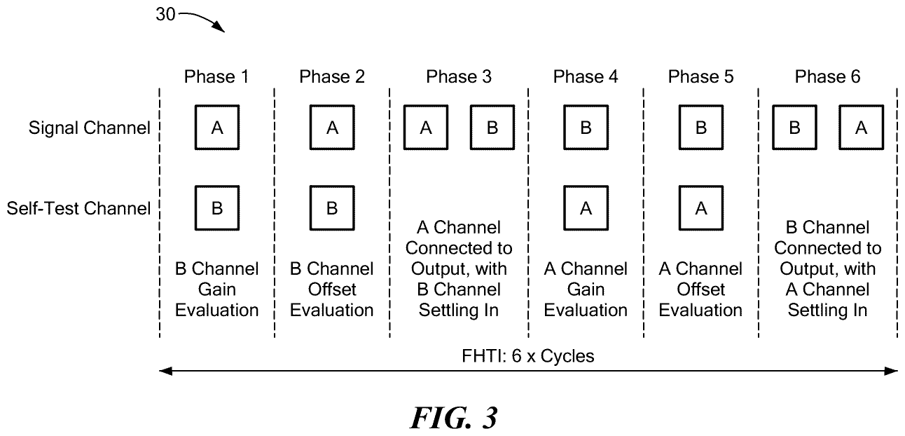

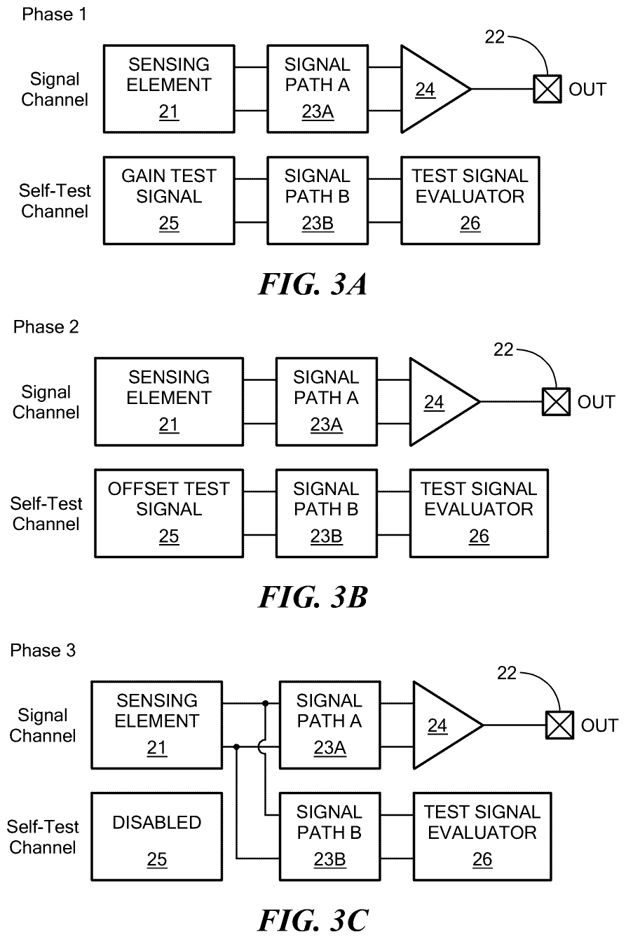

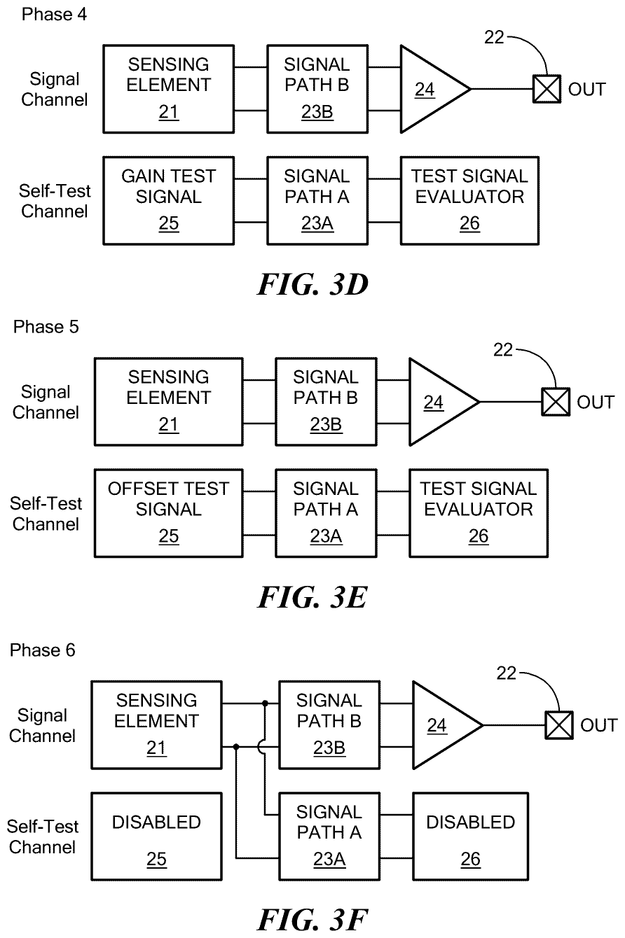

The control circuit 29 functions to select, over time, various signal paths for self-testing. Embodiments include an extra signal path (shown as signal path 23B in FIG. 2), which may be used to divert a data signal away from its normal signal path (shown as signal path 23A in FIG. 2). Once the spare signal path is stable, the normal signal path may be disconnected from its useful endpoints (i.e., the sensing element 21 and the sensor output 22) and reconnected to the testing means (i.e., the test signal generator 25 and the test signal evaluator 26). This process may be repeated as often as necessary, and in whatever pattern is desired. Advantageously, the control circuit 29 may select signal paths cyclically for testing, as shown in FIG. 3.

FIG. 3 shows a timing diagram for a self-test protocol 30 according to an embodiment that may be performed by the sensor 20 of FIG. 2 or another device having two signal paths A and B. The self-test protocol 30 has six phases, and FIGS. 3A-3F schematically show the operation of the system of FIG. 2 at respective phases of the timing diagram shown in FIG. 3.

With reference to FIGS. 3 and 3A-3C, the “signal channel” in Phases 1-3 of the self-test protocol comprises the sensing element 21, the sensor output 22, and signal path A 23A while the “self-test channel” comprises the test signal generator 25, the test signal evaluator 26, and the signal path B 23B. With reference to FIGS. 3 and 3D-3F, the “signal channel” in Phases 4-6 of the self-test protocol comprises the sensing element 21, the sensor output 22, and signal path B 23B while the “self-test channel” comprises the test signal generator 25, the test signal evaluator 26, and the signal path A 23A. The path couplers 27, 28 and the control circuit 29 are omitted from these figures; the figures instead show how the path couplers and control circuit cooperate to adjust which inputs are connected to which outputs. The entire six phases may occur within one fault detection time interval (FDTI) or one fault handling time interval (FHTI) as the case may be.

With reference to FIG. 3 and FIG. 3A, Phase 1 of the self-test protocol tests the spare signal path 23B using an amplifier gain evaluation. That is, the test signal evaluator 26 evaluates a gain test signal generated by the test signal generator 25 and processed by the selected signal path 23B, and signals any fault.

With reference to FIG. 3 and FIG. 3B, Phase 2 of the self-test protocol tests the spare signal path 23B using a notch filter offset evaluation. That is, the test signal evaluator 26 evaluates an offset test signal generated by the test signal generator 25 and processed by the selected signal path 23B, and signals any fault.

With reference to FIG. 3 and FIG. 3C, Phase 3 of the self-test protocol disconnects the selected signal path 23B from the test signal generator 25 and the test signal evaluator 26, and connects it to the sensing element 21 and the sensor output 22. Phase 3 lasts until the selected signal path 23B “settles in” and reliably conveys the data signal. Then, the control circuit selects signal path 23A for self-test, in accordance with a cyclic ordering of the signal paths, disconnecting the newly-selected signal path 23A from the sensing element 21 and the sensor output 22, and connecting it to the test signal generator 25 and the test signal evaluator 26.

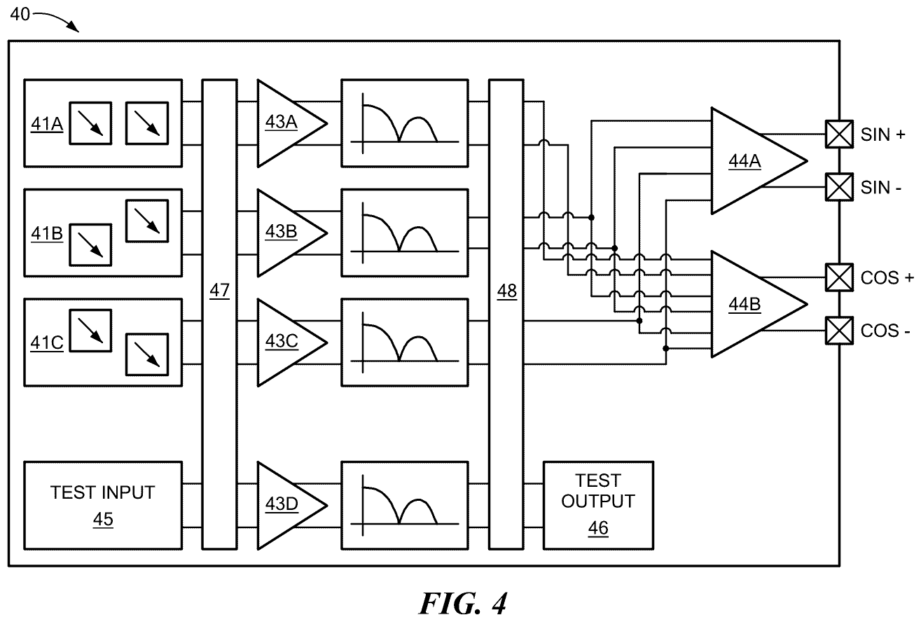

In particular, the control circuit identifies two signal paths that each maintain a data connection between the sensing element and the sensor output, then selects one of the two identified signal paths for testing. This two-step process also may be applied to multiple sensing elements, each coupled to the sensor output through corresponding signal paths, and to a sensing element that is coupled to multiple outputs through corresponding signal paths (e.g., as shown in FIG. 4 and described below).

The process then repeats with signal path 23A in place of signal path 23B. Thus, with reference to FIG. 3 and FIG. 3D, Phase 4 of the self-test protocol tests the signal path 23A using an amplifier gain evaluation. That is, the test signal evaluator 26 evaluates a gain test signal generated by the test signal generator 25 and processed by the selected signal path 23A, and signals any fault.

With reference to FIG. 3 and FIG. 3E, Phase 5 of the self-test protocol tests the signal path 23A using a notch filter offset evaluation. That is, the test signal evaluator 26 evaluates an offset test signal generated by the test signal generator 25 and processed by the selected signal path 23A, and signals any fault.

Finally, with reference to FIG. 3 and FIG. 3F, Phase 6 of the self-test protocol disconnects the selected signal path 23A from the test signal generator 25 and the test signal evaluator 26, and reconnects it to the sensing element 21 and the sensor output 22. Phase 6 lasts until the selected signal path 23A “settles in” and reliably conveys the data signal. Then, the control circuit again selects signal path 23B for self-test, in accordance with a cyclic ordering of the signal paths, disconnecting the newly-selected signal path 23B from the sensing element 21 and the sensor output 22, and connecting it to the test signal generator 25 and the test signal evaluator 26. At this point, the circuit is again in the condition it was prior to phase 1, and the self-test protocol may begin again.

As explained above, the concepts, techniques, and structures may be embodied using multiple sensors and multiple outputs. In this connection, FIG. 4 schematically shows relevant components of a system 40 having three magnetic field sensing elements and a test generator according to another embodiment. Each sensing element 41A, 41B, 41C includes two Hall elements having a unique physical arrangement that permits detection of a magnetic field vector. Each signal channel 43A, 43B, 43C includes an amplifier and a notch filter coupled to multiple output amplifiers and pins. In embodiments, a parallel channel is provided having a test signal generator 45 providing a test input, an identical signal path 43D, and a test signal evaluator 46 providing a test output. The input path coupler 47 and the output path coupler 48 may operate in the manner described above in connection with FIG. 2; i.e., routing the test input to the test output using a selected signal path while routing each sensing element to its assigned output through a non-selected signal path.

The system 40 shows that each of the sensing elements 41A, 41B, 41C is connected to each of the two output amplifiers 44A, 44B. Thus, a plurality of sensing elements are each coupled to a different input of the first path coupler. It is further seen that a plurality of sensor outputs are each coupled to a different output of the second path coupler. Thus, maintaining the data connection between the sensor elements and the sensor outputs has a many-to-many relationship. It is contemplated that embodiments with only one sensing element but multiple outputs may use a data connection having a one-to-many relationship, and that embodiments with multiple sensing elements but only one output may use a data connection having a many-to-one relationship.

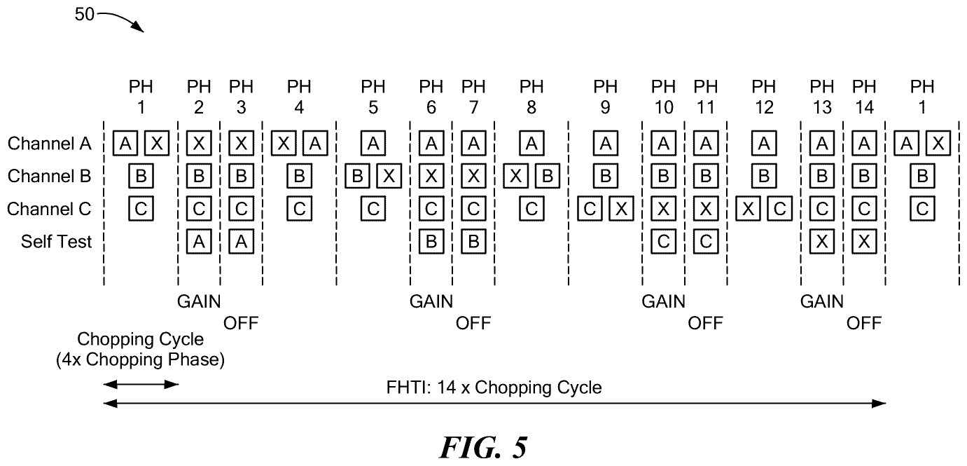

FIG. 5 shows a timing diagram 50 for a method according to an embodiment that may be performed by the system 40 of FIG. 4. The timing diagram 50 tests four signal paths (indicated by blocks A, B, C, and X) that correspond to three signal channels and one self-test channel shown in FIG. 4. However, because the method illustrated in FIG. 5 tests four signal paths rather than the two tested as indicated in FIG. 3, more phases are required. Indeed, FIG. 5 shows 14 phases to test the four signal paths A, B, C, and X. However, the operations performed during each phase are explained above in connection with FIGS. 2, 3, and 3A-3F and for brevity are not repeated here.

FIG. 5 is provided to illustrate one possible test sequence for the four signal paths A, B, C, and X. Other test sequences may be used in accordance with embodiments. Moreover, the use of three signal channels and one test channel in FIGS. 4 and 5 is merely illustrative, not limiting, and it is appreciated that other numbers of signal channels and test channels may be present in an embodiment. For example, a sensor having a large number of signal channels may require more than one test channel to provide testing of multiple signal paths at once, thereby reducing the time to test all signal paths to thereby comply with safety requirements.

In general, a complete self-test cycle will test each of a number N of signal channels and 1 test channel. For example, N=1 in FIG. 2 and N=3 in FIG. 5. Because signal channels carry useful sense signals that always must be coupled to the sensor output, whenever a signal path is connected to a signal channel it should “settle in” for a time (i.e., one phase). Thus, the “extra” signal path associated with the test channel (denoted B in FIG. 3 and X in FIG. 5) uses one phase to settle when it is connected to a signal channel (e.g., Phase 3 in FIG. 3 and Phases 1, 5, and 9 in FIG. 5), and the signal path associated with that signal channel will require one phase to settle back in when it is reconnected to the channel (e.g., Phase 6 in FIG. 3 and Phases 4, 8, and 12 in FIG. 5). If each signal path self-test has T functional testing phases, then adding in these settling phases yields a total of T+2 phases to fully test each signal channel. In FIGS. 2 and 5, each signal path is tested for gain and offset so T=2, and each signal channel requires four phases as indicated. It is appreciated that other embodiments may have different numbers T of functions to test in each signal path.

However, because the self-test channel does not carry useful sense signals, no settling period is required after connecting any signal path to that channel. Note, for example, the lack of a settling phase between Phases 1 and 2 (for signal path A). Therefore, only T phases are required to test the “extra” signal path (e.g., Phases 13 and 14 in FIG. 5). Combining results, an embodiment may use N(T+2)+T phases to self-test all signal paths. As expected, this formula indicates six phases for one signal channel and one self-test channel (as shown in FIG. 3) and fourteen phases for three signal channels and one self-test channel (as shown in FIG. 5). A person having ordinary skill in the art will be able to modify this formula for use with multiple test channels as described above.

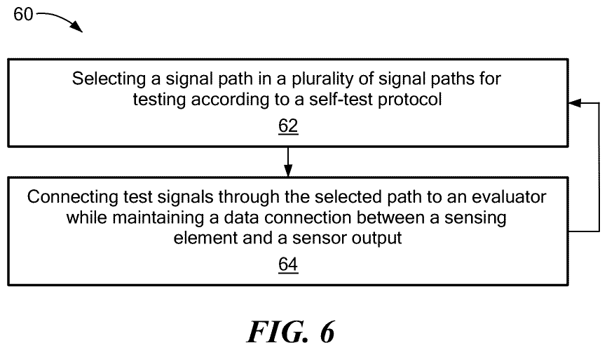

FIG. 6 is a flow diagram for a method 60 according to various embodiments. The method 60 operates on a sensor within a housing, the sensor comprising a first path coupler and a second path coupler wherein outputs of the first path coupler are coupled to respective inputs of the second path coupler via a plurality of signal paths. Thus, for example, the method 60 may be performed by the sensor 20 or the system 40, or by another sensor or device in accordance with the concepts, techniques, and structures disclosed herein. In various embodiments, the sensor comprises a magnetic field sensor and the sensing element comprises one or more magnetic field sensing elements.

The method 60 includes a first process 62 selecting a signal path in the plurality of signal paths for testing. Selecting the signal path includes changing the selected signal path over time according to a self-test protocol. In some embodiments, signal paths are selected cyclically. The process 62 may include identifying two signal paths that each maintain a data connection between the sensing element and the sensor output; and selecting one of the two identified signal paths for testing.

The method 60 also includes a second process 64, responsive to the selecting of process 62, for configuring the first and second path couplers to connect test signals, produced by a test signal generator connected to a first input of the first path coupler, through the selected signal path to a test signal evaluator connected to a first output of the second path coupler. This connection is performed while maintaining a data connection between a sensing element connected to a second input of the first path coupler and a sensor output connected to a second output of the second path coupler.

In various embodiments, the test signal generator produces test signals to test different signal processes performed within the selected signal path. Such test signals may include, for example, an amplifier gain test signal, or a notch filter offset test signal, or both.

Connecting the test signals may be performed in phases, e.g., as summarized in FIGS. 3 and 5 and detailed in FIGS. 3A-3F. Some of the phases include disconnecting the selected signal path from the sensing element and the sensor output, and connecting the selected signal path to the test signal generator and the test signal evaluator. Other phases include evaluating, by the test signal evaluator, a test signal generated by the test signal generator and processed by the selected signal path. And other phases include disconnecting the selected signal path from the test signal generator and the test signal evaluator, and connecting the selected signal path to the sensing element and the sensor output.

Finally, as described above, it is contemplated that embodiments of the method 60 that operate on sensors with only one sensing element but multiple outputs may use a data connection having a one-to-many relationship, and that embodiments that operate on sensors with multiple sensing elements but only one output may use a data connection having a many-to-one relationship.

It is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

In illustrative implementations of the concepts described herein, one or more computers (e.g., integrated circuits, microcontrollers, controllers, microprocessors, processors, field-programmable-gate arrays, personal computers, onboard computers, remote computers, servers, network hosts, or client computers) may be programmed and specially adapted: (1) to perform any computation, calculation, program or algorithm described or implied above; (2) to receive signals indicative of human input; (3) to output signals for controlling transducers for outputting information in human perceivable format; (4) to process data, to perform computations, to execute any algorithm or software, and (5) to control the read or write of data to and from memory devices. The one or more computers may be connected to each other or to other components in the system either: (a) wirelessly, (b) by wired or fiber optic connection, or (c) by any combination of wired, fiber optic or wireless connections.

In illustrative implementations of the concepts described herein, one or more computers may be programmed to perform any and all computations, calculations, programs and algorithms described or implied above, and any and all functions described in the immediately preceding paragraph. Likewise, in illustrative implementations of the concepts described herein, one or more non-transitory, machine-accessible media may have instructions encoded thereon for one or more computers to perform any and all computations, calculations, programs and algorithms described or implied above, and any and all functions described in the immediately preceding paragraph.

For example, in some cases: (a) a machine-accessible medium may have instructions encoded thereon that specify steps in a software program; and (b) the computer may access the instructions encoded on the machine-accessible medium, in order to determine steps to execute in the software program. In illustrative implementations, the machine-accessible medium may comprise a tangible non-transitory medium. In some cases, the machine-accessible medium may comprise (a) a memory unit or (b) an auxiliary memory storage device. For example, in some cases, while a program is executing, a control unit in a computer may fetch the next coded instruction from memory.

In some cases, one or more computers are programmed for communication over a network. For example, in some cases, one or more computers are programmed for network communication: (a) in accordance with the Internet Protocol Suite, or (b) in accordance with any other industry standard for communication, including any USB standard, ethernet standard (e.g., IEEE 802.3), token ring standard (e.g., IEEE 802.5), or wireless communication standard, including IEEE 802.11 (Wi-Fi®), IEEE 802.15 (Bluetooth®/Zigbee®), IEEE 802.16, IEEE 802.20, GSM (global system for mobile communications), UMTS (universal mobile telecommunication system), CDMA (code division multiple access, including IS-95, IS-2000, and WCDMA), LTE (long term evolution), or 5G (e.g., ITU IMT-2020).

Features of embodiments may take various forms of communication devices, both wired and wireless; television sets; set top boxes; audio/video devices; laptop, palmtop, desktop, and tablet computers with or without wireless capability; personal digital assistants (PDAs); telephones; pagers; satellite communicators; cameras having communication capability; network interface cards (NICs) and other network interface structures; base stations; access points; integrated circuits; as instructions and/or data structures stored on machine readable media; and/or in other formats. Examples of different types of machine readable media that may be used include floppy diskettes, hard disks, optical disks, compact disc read only memories (CD-ROMs), digital video disks (DVDs), Blu-ray disks, magneto-optical disks, read only memories (ROMs), random access memories (RAMs), erasable programmable ROMs (EPROMs), electrically erasable programmable ROMs (EEPROMs), magnetic or optical cards, flash memory, and/or other types of media suitable for storing electronic instructions or data.

As used herein, “including” means including without limitation. As used herein, the terms “a” and “an”, when modifying a noun, do not imply that only one of the noun exists. As used herein, unless the context clearly indicates otherwise, “or” means and/or. For example, A or B is true if A is true, or B is true, or both A and B are true. As used herein, “for example”, “for instance”, “e.g.”, and “such as” refer to non-limiting examples that are not exclusive examples. The word “consists” (and variants thereof) are to be give the same meaning as the word “comprises” or “includes” (or variants thereof).

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “at least one” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description herein, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the specification to modify an element does not by itself connote any priority, precedence, or order of one element over another or the temporal order in which acts of a method are performed, but are used merely as labels to distinguish one element having a certain name from another element having a same name (but for use of the ordinal term) to distinguish the elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

What is claimed is:

1. A sensor comprising a housing that includes:
a first path coupler and a second path coupler, wherein outputs of the first path coupler are coupled to respective inputs of the second path coupler via a plurality of signal paths;
a sensing element and a test signal generator, each coupled to a different input of the first path coupler;
a sensor output and a test signal evaluator, each coupled to a different output of the second path coupler; and
a control circuit coupled to and configuring the first and second path couplers to connect test signals, produced by the test signal generator, to the test signal evaluator through a selected signal path in the plurality of signal paths, while maintaining a data connection between the sensing element and the sensor output using a non-selected signal path in the plurality of signal paths;
wherein the control circuit is configured to change the selected signal path over time according to a self-test protocol.

2. The sensor according to claim 1, wherein the sensor comprises a magnetic field sensor and the sensing element comprises one or more magnetic field sensing elements.

3. The sensor according to claim 1, wherein the test signal generator comprises a circuit configured to generate signals to test different signal processes performed within a signal path in the plurality of signal paths.

4. The sensor according to claim 3, wherein the test signal generator comprises a circuit configured to generate an amplifier gain test signal, or a notch filter offset test signal, or both.

5. The sensor according to claim 1, wherein each signal path in the plurality of signal paths comprises an amplifier, or a notch filter, or both.

6. The sensor according to claim 1, wherein the control circuit is configured to select signal paths cyclically for testing.

7. The sensor according to claim 1, wherein the self-test protocol includes a plurality of phases, each phase consisting of:
(a) disconnecting the selected signal path from the sensing element and the sensor output, and connecting the selected signal path to the test signal generator and the test signal evaluator; or
(b) evaluating, by the test signal evaluator, a test signal generated by the test signal generator and processed by the selected signal path; or
(c) disconnecting the selected signal path from the test signal generator and the test signal evaluator, and connecting the selected signal path to the sensing element and the sensor output.

8. The sensor according to claim 7, wherein the self-test protocol includes:
identifying two signal paths that each maintain a data connection between the sensing element and the sensor output; and
selecting one of the two identified signal paths for testing.

9. The sensor according to claim 1, wherein the sensing element comprises a plurality of sensing elements, each coupled to a different input of the first path coupler, and maintaining the data connection comprises maintaining a data connection between the plurality of sensing elements and the sensor output.

10. The sensor according to claim 1, wherein the sensor output comprises a plurality of sensor outputs, each coupled to a different output of the second path coupler, and maintaining the data connection comprises maintaining a data connection between the sensing element and the plurality of sensor outputs.

11. A method of testing a sensor within a housing, the sensor comprising a first path coupler and a second path coupler wherein outputs of the first path coupler are coupled to respective inputs of the second path coupler via a plurality of signal paths, the method comprising:
selecting a signal path in the plurality of signal paths for testing; and
responsive to the selecting, configuring the first and second path couplers to connect test signals, produced by a test signal generator connected to a first input of the first path coupler, through the selected signal path to a test signal evaluator connected to a first output of the second path coupler, while maintaining a data connection between a sensing element connected to a second input of the first path coupler and a sensor output connected to a second output of the second path coupler,
wherein selecting the signal path comprises changing the selected signal path over time according to a self-test protocol.

12. The method according to claim 11, wherein the sensor comprises a magnetic field sensor and the sensing element comprises one or more magnetic field sensing elements.

13. The method according to claim 11, further comprising the test signal generator generating test signals to test different signal processes performed within a signal path in the plurality of signal paths.

14. The method according to claim 13, wherein the test signals comprise an amplifier gain test signal, or a notch filter offset test signal, or both.

15. The method according to claim 11, wherein each signal path in the plurality of signal paths comprises an amplifier, or a notch filter, or both.

16. The method according to claim 11, wherein selecting the signal path comprises selecting signal paths cyclically for testing.

17. The method according to claim 11, wherein the self-test protocol includes a plurality of phases, each phase consisting of:
(a) disconnecting the selected signal path from the sensing element and the sensor output, and connecting the selected signal path to the test signal generator and the test signal evaluator; or
(b) evaluating, by the test signal evaluator, a test signal generated by the test signal generator and processed by the selected signal path; or
(c) disconnecting the selected signal path from the test signal generator and the test signal evaluator, and connecting the selected signal path to the sensing element and the sensor output.

18. The method according to claim 17, wherein the self-test protocol includes:
identifying two signal paths that each maintain a data connection between the sensing element and the sensor output; and
selecting one of the two identified signal paths for testing.

19. The method according to claim 11, wherein the sensing element comprises a plurality of sensing elements, each coupled to a different input of the first path coupler, and maintaining the data connection comprises maintaining a data connection between the plurality of sensing elements and the sensor output.

20. The method according to claim 11, wherein the sensor output comprises a plurality of sensor outputs, each coupled to a different output of the second path coupler, and maintaining the data connection comprises maintaining a data connection between the sensing element and the plurality of sensor outputs.
